(19) United States
(12) Patent Application Publication
(10) Pub. No.: US 2024/0079523 A1
(43) Pub. Date: Mar. 7, 2024

(54) Light-Emitting Device, Display Device Including the Same, and Method for Manufacturing the Same

(71) Applicant: LG Display Co., Ltd., Seoul (KR)

(72) Inventors: Dongwon Yang, Seoul (KR); Jung-Hun Choi, Paju-si (KR)

(21) Appl. No.: 18/452,130

(22) Filed: Aug. 18, 2023

(30) Foreign Application Priority Data
Sep. 5, 2022 (KR) 10-2022-0112280

(51) Int. Cl. H01L 33/20; H01L 25/075; H01L 33/00; H01L 33/44

(52) U.S. Cl. CPC H01L 33/20; H01L 25/0753; H01L 33/007; H01L 33/0093; H01L 33/44; H01L 33/325

(57) ABSTRACT

The present disclosure relates to a light-emitting device, display device including the same, and method for manufacturing the same. A light-emitting device includes a nitride semiconductor structure including a first semiconductor layer, an active layer and a second semiconductor layer; and a passivation pattern at least partially surrounding an outer side surface of the nitride semiconductor structure, wherein the nitride semiconductor comprises a convex hemispherical shape.

### CROSS-REFERENCE TO RELATED APPLICATION

This application claims priority from Republic of Korea Patent Application No. 10-2022-0112280 filed on Sep. 5, 2022 in the Korean Intellectual Property Office, and all the benefits accruing therefrom under 35 U.S.C. 119, which is hereby incorporated by reference in its entirety.

### BACKGROUND

### Field

The present disclosure relates to a light-emitting device, a display device including the light-emitting device, and a method for manufacturing the light-emitting device. More specifically, the present disclosure relates to a light-emitting device capable of preventing or at least reducing damage to the light-emitting device, a display device including the light-emitting device, and a method for manufacturing the light-emitting device.

### Description of Related Art

A display device is applied to various electronic devices such as TVs, mobile phones, laptops, and tablets.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and high image quality compared to the organic light-emitting display device.

Further, the micro-LED display device is resistant to the external environment, the micro-LED display device does not require a protective structure such as a sealing material, and various types of materials may be used as a material of a substrate of the device, thereby implementing a flexible display device with a thinner structure than that of the organic light-emitting display device. Thus, the micro-LED display device is in the limelight as a next-generation display device.

### SUMMARY

A purpose according to embodiments of the present disclosure is to provide a light-emitting device that prevents or at least reduces a side surface of a nitride semiconductor structure of the light-emitting device from being damaged, thereby securing an area where combinations of electrons and holes that participate in light emission occurs.

Further, a purpose according to embodiments of the present disclosure is to vary a shape of the nitride semiconductor structure to improve light-emitting efficiency thereof.

Further, a purpose according to embodiments of the present disclosure is to reduce a distance between electrodes constituting a light-emitting device to allow current injection to be easy to reduce resistance.

Further, a purpose according to embodiments of the present disclosure is to provide a manufacturing method in which micro-sized light-emitting elements area is easily aligned on a display device.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In one embodiment, a light-emitting device comprises: a nitride semiconductor structure including a first semiconductor layer, an active layer on the first semiconductor layer, and a second semiconductor layer on the active layer; and a passivation pattern at least partially surrounding an outer side surface of the nitride semiconductor structure, wherein the nitride semiconductor structure comprises a convex hemispherical shape.

In one embodiment, a display device comprises: a package substrate; a first electrode on the package substrate; a light-emitting element on the first electrode, the light-emitting element including: a nitride semiconductor structure having a convex hemispherical shape, the nitride semiconductor structure including a first semiconductor layer, an active layer on the first semiconductor layer, and a second semiconductor layer on the active layer; and a passivation pattern at least partially surrounding an outer side surface of the nitride semiconductor structure, and a second electrode on the first semiconductor layer of the light-emitting element.

In one embodiment, a method for manufacturing a light-emitting device comprises: providing a growth substrate; forming a trench in the growth substrate, the trench having a concave shape; forming a passivation pattern on an inner surface of the trench without completely covering the inner surface of the trench; forming a nitride semiconductor structure by filling the trench with the nitride semiconductor structure; forming a conductive layer on the nitride semiconductor structure in the trench; and removing the growth substrate from the nitride semiconductor structure.

In one embodiment, a light-emitting device comprises: a nitride semiconductor structure having a planar lower surface and a convex upper surface that extends from the planar lower surface in a direction away from the planar lower surface, the nitride semiconductor structure including an active layer configured to emit light; and a passivation pattern that surrounds at least a portion of the convex upper surface of the nitride semiconductor structure.

According to the embodiments of the present disclosure, the side surface of the nitride semiconductor structure of the light-emitting element can be prevented from being damaged, thereby increasing an area where combination of electrons-holes that participates in light emission occurs.

Further, according to the embodiments of the present disclosure, the light-emitting element has the hemispherical shape having one surface being flat and the other surface being opposite thereto and being convex, thereby increasing the light-emitting area and thus improving light emission efficiency.

In addition, the first semiconductor layer, the active layer, and the second semiconductor layer may be stacked in the vertical direction. Thus, a wiring may extend in the vertical direction, thereby reducing the number of process steps for forming the pixel, and thus improving process efficiency.

In addition, the light-emitting element has the convex hemispherical shape. Thus, the light-emitting element may be easily displaced or rotated or turned upside down in a process for aligning or orienting the light-emitting element on the package substrate of the display device, thereby preventing misalignment or incorrect orientation.

In addition, in the light-emitting element according to the embodiment of the present disclosure, the anode electrode and the cathode electrode can be positioned in the same layer and on the package substrate of the display device. Thus, the number of deposition process steps for forming the pixel may be reduced. The process efficiency may be improved.

In addition, a spacing between the electrodes may be reduced. Accordingly, easy current injection may be achieved to lower the electrical resistance.

Effects of the present disclosure are not limited to the effects mentioned above, and other effects not mentioned will be clearly understood by those skilled in the art from the descriptions below.

### BRIEF DESCRIPTION OF DRAWINGS

FIGS. 1A to 1E are diagrams for illustrating a method for manufacturing a light-emitting element according to a first embodiment of the present disclosure.

FIG. 2A and FIG. 2B are diagrams for illustrating a light-emitting element according to a second embodiment of the present disclosure.

FIG. 3 is a diagram for illustrating a light-emitting element according to a third embodiment of the present disclosure.

FIG. 4A and FIG. 4B are diagrams for illustrating a light-emitting element according to a fourth embodiment of the present disclosure.

FIG. 5 to FIG. 14 are diagrams for illustrating a method for manufacturing the light-emitting element according to the second embodiment of the present disclosure.

FIG. 15 to FIG. 19 are diagrams for illustrating a method for manufacturing the light-emitting element according to the third embodiment of the present disclosure.

FIG. 20 to FIG. 30 are diagrams for illustrating a method for manufacturing the light-emitting element according to the fourth embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly connected to or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Description.

Hereinafter, a light-emitting element according to each embodiment of the present disclosure will be described with reference to the accompanying drawings.

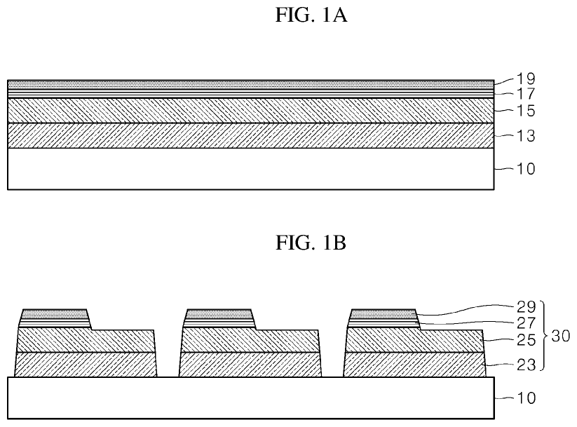

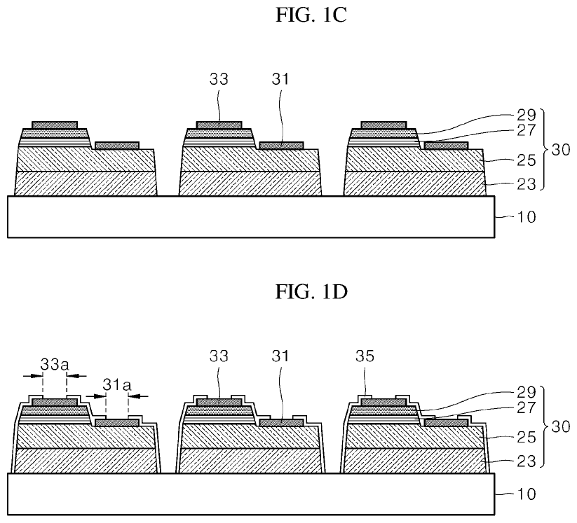

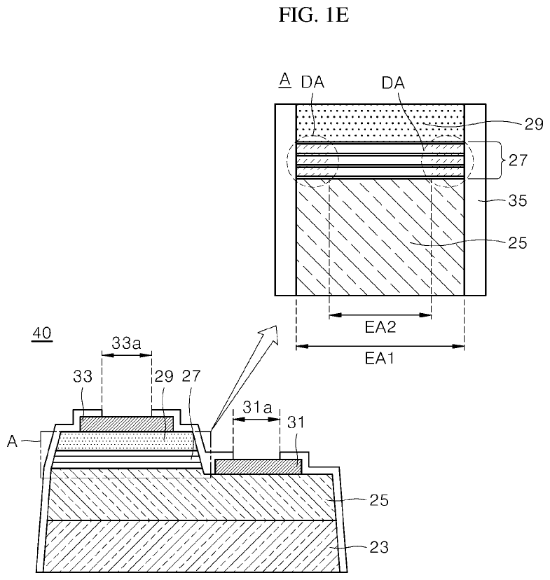

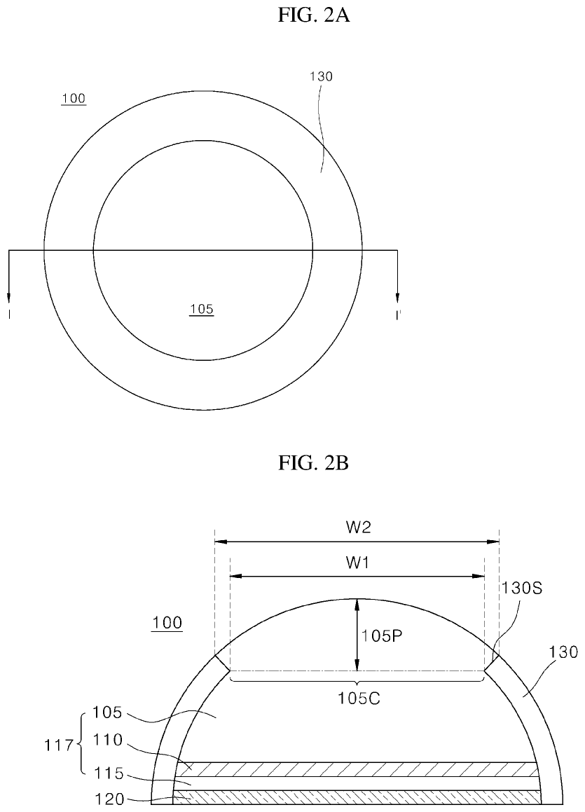

FIGS. 1A to 1E are diagrams for illustrating a method for manufacturing a light-emitting element according to a first embodiment of the present disclosure. FIG. 2 is a plan view of the light-emitting element according to the first embodiment.

Referring to FIG. 1A, an undoped semiconductor material layer 13, a first semiconductor material layer 15, an active material layer 17, and a second semiconductor material layer 19 are sequentially stacked on a growth substrate 10. In this regard, FIG. 1A is a cross-sectional view taken along a line I-P of FIG. 2A.

The growth substrate 10 may include a material such as sapphire, silicon (Si), silicon carbide (SiC) or gallium arsenide (GaAs). However, the present disclosure is not limited thereto. The undoped semiconductor material layer 13 may include an undoped nitride semiconductor. For example, the nitride semiconductor may be made of a GaN-based semiconductor material.

The first semiconductor material layer 15 may be formed on the undoped semiconductor material layer 13 and include a nitride semiconductor containing first conductivity-type impurities. For example, the first conductivity-type impurities may include N-type impurities. The nitride semiconductor may be made of a GaN-based semiconductor material including GaN, AlGaN, InGaN, or AlInGaN. The n-type impurities contained in the first semiconductor material layer 15 may include silicon (Si), germanium (Ge), selenium (Se) or carbon (C).

The active material layer 17 is formed on the first semiconductor material layer 15. The active material layer 17 is a layer for emitting light, and may have a multi-quantum well (MQW) structure having a well layer and a barrier layer having a higher band gap than that of the well layer. For example, the active material layer 17 may be composed of an InGaN layer as the well layer and an AlGaN layer as the barrier layer.

The second semiconductor material layer 19 is formed on the active material layer 17. The second semiconductor material layer 19 may include a nitride semiconductor containing second conductivity-type impurities. For example, the second conductivity-type impurities may include P-type impurities. The nitride semiconductor may be made of a GaN-based semiconductor material including GaN, AlGaN, InGaN, or AlInGaN. The P-type impurities contained in the second semiconductor material layer 19 may include manganese (Mg), zinc (Zn), or beryllium (Be). In one example, in the present disclosure, an example in which the first semiconductor material layer 15 and the second semiconductor material layer 19 are made of the nitride semiconductor containing the N-type impurities and the nitride semiconductor including the P-type impurities, respectively is described. However, the present disclosure is not limited thereto. In another example, the first semiconductor material layer 15 and the second semiconductor material layer 19 may be made of a nitride semiconductor containing the P-type impurities and a nitride semiconductor containing the N-type impurities, respectively.

Referring to FIG. 1B, the second semiconductor material layer 19, the active material layer 17, the first semiconductor material layer 15, and the undoped semiconductor material layer 13 are patterned to form nitride semiconductor structures 30 disposed on the growth substrate 10 so as to be spaced apart from each other.

Each of the patterned nitride semiconductor structures 30 may include an undoped semiconductor layer 23, a first semiconductor layer 25, an active layer 27, and a second semiconductor layer 29. In this regard, the patterning process may be performed in a mesa etching manner to expose a portion of a surface of the first semiconductor layer 25. Such mesa etching may be performed in a dry etching scheme. The dry etching scheme may be carried out using an inductively coupled plasma-reactive ion etch (ICP-RIE) using reactive gas.

However, in performing the patterning process in the dry etching scheme, damage may occur on each of both opposing side surfaces of the nitride semiconductor structure 30, resulting in decrease in light-emitting efficiency. A detailed description thereof will be made later.

Referring to FIG. 1C, an electrode material layer is formed on the nitride semiconductor structure 30 and then is patterned, such that a first electrode 31 is formed on a surface of the first semiconductor layer 25 exposed by performing the mesa etching, while a second electrode 33 is formed on the second semiconductor layer 29. Each of the first electrode 31 and the second electrode 33 may be made of at least one metal of, for example, Au, W, Pt, Ir, Ag, Cu, Ni, Ti, Cr, or an alloy thereof.

Referring to FIG. 1D, a passivation layer is formed on the nitride semiconductor structure 30 and an etching process is performed thereon. Thus, a passivation pattern 35 having open areas 31a and 33a defined therein in which the first electrode 31 and the second electrode 33 are partially exposed is formed. The passivation pattern 35 may be formed to cover a portion of a surface of an edge of each of the first electrode 31 and the second electrode 33 while covering an outer side surface of the nitride semiconductor structure 30.

The passivation pattern 35 serves to cure damaged portions occurring on both opposing side surfaces of the nitride semiconductor structure 30 during the dry etching process to form the nitride semiconductor structure 30 of FIG. 1B.

The growth substrate 10 is then removed from the nitride semiconductor structure 30 and then individual light-emitting elements 40 are obtained in a separate manner A single individual light-emitting element 40 is as shown in FIG. 1E. In this regard, the growth substrate 10 may be removed therefrom in a laser lift off (LLO) manner.

In one example, when the dry etching using the inductively coupled plasma is performed in a state in which undoped semiconductor material layer 13, the first semiconductor material layer 15, the active material layer 17, and the second semiconductor material layer 19 are stacked, as shown in FIG. 1B, damage by the plasma may occur on both opposing side surfaces of the light-emitting element 40 as indicated in ‘A’ as an enlarged view of both opposing side surfaces of the light-emitting element 40 in FIG. 1E.

Specifically, when the plasma is applied to the stack in which the undoped semiconductor material layer 13, the first semiconductor material layer 15, the active material layer 17, and the second semiconductor material layer 19 are stacked, the first semiconductor material layer 15, the active material layer 17, and the second semiconductor material layer 19 are directly exposed to plasma, such that an intermolecular bond is broken and thus a carrier trap site is created. This carrier trap site is unstable. Thus, many non-light-emitting combinations of electron-holes that do not participate in light emission may occur at this site.

Since a micro-LED has a size smaller than 100 micrometers (μm), a percentage of a size of a sidewall area where many of these non-light-emitting combinations occur relative to a total area size of the micro-LED is relatively large. Accordingly, upon application of the same current thereto, the light-emitting efficiency is greatly reduced.

Accordingly, a target size of the light-emitting area is ‘EA1’. However, a number of abnormal combinations of electrons and holes that do not participate in light emission may occur on each of both opposing side surfaces due to the plasma damage. Thus, size of a light-emitting area may be reduced by a size of a damaged area DA from each of both opposing side surfaces. Thus, an actual size of the light-emitting area is ‘EA2’, which is smaller than the target light-emitting area size EA1. Thus, on application of the same current thereto, luminance in the damaged area DA is relatively lower than luminance in the actual light-emitting area EA2. Thus, the light-emitting efficiency is greatly reduced.

In addition, after the nitride semiconductor structure 30 is formed, the passivation layer is formed thereon, and the etching process is performed thereon to form the open areas 31a and 33a for partially exposing the first electrode 31 and the second electrode 33, respectively. Thus, an additional process for forming the open areas 31a and 33a inevitably occurs. Thus, a manufacturing yield of the light-emitting element may be reduced due to an alignment defect that may occur during the additional process.

Accordingly, in another embodiment of the present disclosure, a light-emitting element capable of preventing or at least reducing the increase in abnormal combinations of electron-holes that do not participate in light emission, thereby increasing light-emitting efficiency, a display device including the light-emitting element, and a method for manufacturing the light-emitting element will be described. The present disclosure will be described with reference to the drawings below.

FIG. 2A and FIG. 2B are diagrams for illustrating a light-emitting element according to a second embodiment of the present disclosure. In this regard, FIG. 2B is a cross-sectional view of FIG. 2A cut along a line I-P.

Referring to FIG. 2A and FIG. 2B, a light-emitting element 100 according to the second embodiment of the present disclosure includes a nitride semiconductor structure 117, a conductive layer 120 positioned on one surface of the nitride semiconductor structure 117, and a passivation pattern 130.

The nitride semiconductor structure 117 may have a shape in which a first semiconductor layer 105, an active layer 110, and a second semiconductor layer 115 are sequentially stacked. The conductive layer 120 may be disposed in contact with one surface of the second semiconductor layer 115 as the lowermost layer of the nitride semiconductor structure 117.

The passivation pattern 130 may have a shape surrounding an outer side surface of the conductive layer 120 and a portion of an outer side surface of the nitride semiconductor structure 117. Specifically, the passivation pattern 130 may have a shape surrounding an outer side surface of each of the second semiconductor layer 115 and the active layer 110 of the nitride semiconductor structure 117, and a portion of an outer side surface of the first semiconductor layer 105 thereof. A lower surface of the passivation pattern 130 may be disposed at the same vertical level as that of a lower surface of the conductive layer 120.

The first semiconductor layer 105 may include a protrusion 105P covering an upper surface 130S of the passivation pattern 130. Further, the first semiconductor layer 105 may include a concave portion 105C that has a relatively smaller width in an area where the passivation pattern 130 is disposed. Accordingly, a width W1 of a portion of the first semiconductor layer 105 on which the passivation pattern 130 is disposed is less than a width W2 of a portion of the first semiconductor layer 105 on which the passivation pattern 130 is not disposed.

In one example, in a plan view, the passivation pattern 130 may have a ring shape surrounding a portion other than an exposed portion of the first semiconductor layer 105.

In a cross-sectional view, the light-emitting element 100 according to the second embodiment of the present disclosure may have a hemispherical shape which is upwardly-convex. That is, the nitride semiconductor structure 117 has a planar lower surface and a convex upper surface that extends from the planar lower surface in a direction away from the planar lower surface. The passivation pattern 130 surrounds at least a portion of the convex upper surface of the nitride semiconductor structure 117. In FIG. 2B, the passivation pattern 130 surrounds a portion of the convex upper surface of the nitride semiconductor structure 117 without surrounding a remaining portion of the convex upper surface of the nitride semiconductor structure 117 and without surrounding the planar lower surface of the nitride semiconductor structure 117. Accordingly, compared to a light-emitting element having a flat top surface, a light-emitting area may be increased, and thus light emission efficiency may be increased.

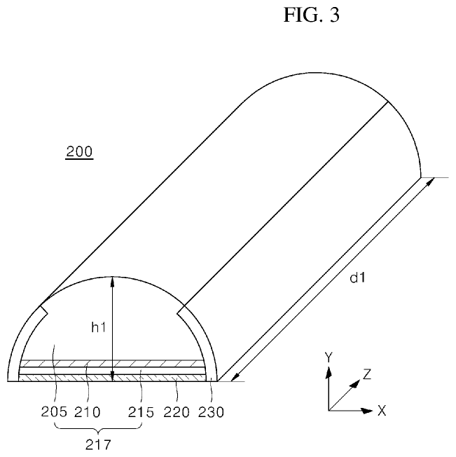

FIG. 3 is a diagram for illustrating a light-emitting element according to a third embodiment of the present disclosure. FIG. 3 has a difference in terms of a shape from the light-emitting element of FIG. 2. Other components are the same or similar as or to each other. The components identical or similar to those of FIG. 2 will be briefly described.

Referring to FIG. 3, a light-emitting element 200 according to the third embodiment of the present disclosure may include a nitride semiconductor structure 217, a conductive layer 220 positioned on one surface of the nitride semiconductor structure 217, and a passivation pattern 230.

The light-emitting element 200 may have a semi-cylindrical shape having a semi-circular cross section. The light-emitting element 200 may have a first length d1 in a Z-axis direction (e.g., a first direction) as a longitudinal direction. The light-emitting element 200 has the first length d1 not exceeding 10 μm. The light-emitting element 200 may have a first height h1 in a Y-axis direction (e.g., a second direction) as a height direction. A ratio of the height and the length of the light-emitting element 200 may be in a range of 1:1 to 1:10.

The nitride semiconductor structure 217 may have a shape in which the first semiconductor layer 205, the active layer 210, and the second semiconductor layer 215 are sequentially stacked in the Y-axis direction as the height direction. The conductive layer 220 may be in contact with one surface of the second semiconductor layer 215.

The passivation pattern 230 may have a shape surrounding an outer side surface of the conductive layer 220 and a portion of an outer side surface of the nitride semiconductor structure 217 formed in the semi-cylindrical shape. Specifically, the passivation pattern 230 may have a shape surrounding an outer side surface of each of the second semiconductor layer 215 and the active layer 210 of the nitride semiconductor structure 217 and a portion of an outer side surface of the first semiconductor layer 205 thereof. That is, the nitride semiconductor structure 217 has a planar lower surface along the X-direction and a convex upper surface along the Y-direction that extends from the planar lower surface in a direction away from the planar lower surface. The passivation pattern 230 surrounds at least a portion of the convex upper surface of the nitride semiconductor structure 217. In FIG. 3, the passivation pattern 230 surrounds a portion of the convex upper surface of the nitride semiconductor structure 217 without surrounding a remaining portion of the convex upper surface of the nitride semiconductor structure 217 and without surrounding the planar lower surface of the nitride semiconductor structure 217. A lower surface of the passivation pattern 230 may be disposed at the same vertical level as that of a lower surface of the conductive layer 220.

In a cross-sectional view, the light-emitting element 200 according to the third embodiment of the present disclosure may have a hemi-circular shape. Accordingly, compared to the light-emitting element having a flat top surface, the light-emitting area size may increase, and thus the light emission efficiency may increase. Further, the light-emitting element 200 has the semi-cylindrical shape having a flat bottom surface (e.g., a planar lower surface). Thus, the conductive layer 220 is integrally formed with the light-emitting element 200. Thus, the light-emitting element 200 may be easily mounted onto the display device.

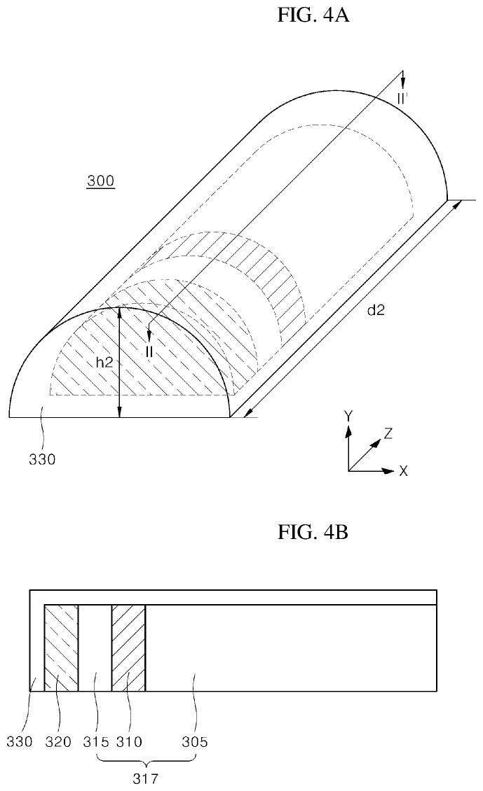

FIG. 4A and FIG. 4B are diagrams for illustrating a light-emitting element according to a fourth embodiment of the present disclosure.

Referring to FIG. 4A and FIG. 4B, a light-emitting element 300 according to the fourth embodiment of the present disclosure includes a nitride semiconductor structure 317, a conductive layer 320 positioned on one surface of the nitride semiconductor structure 317, and a passivation pattern 330.

In a cross-sectional view, the light-emitting element 300 may have a semi-circular shape. The light-emitting element 300 has a semi-cylindrical shape having a flat bottom surface. The light-emitting element 300 may have a second length d2 in the Z-axis direction as a longitudinal direction. The light-emitting element 300 may have the second length not exceeding 10 μm. The light-emitting element 300 may have a second height h2 in the Y-axis direction as a height direction. A ratio of the height and the length of the light-emitting element 300 may be in a range of 1:1 to 1:10.

The nitride semiconductor structure 317 may have a shape in which a first semiconductor layer 305, an active layer 310, and a second semiconductor layer 315 are sequentially stacked in the Z-axis direction as the length direction. The conductive layer 320 may be in contact with one surface of the second semiconductor layer 315.

The passivation pattern 330 may have a shape surrounding a portion of an outer side surface of each of the nitride semiconductor structure 317 and the conductive layer 320 constituting the semi-cylindrical shaped structure. The passivation pattern 330 may cover a portion having a convex shape of the outer side surface of the semi-cylindrical shaped structure composed of the nitride semiconductor structure 317 and the conductive layer 320, and may not cover a flat bottom surface of the semi-cylindrical shaped structure composed of the nitride semiconductor structure 317 and the conductive layer 320. The passivation pattern 330 may cover a side surface of the conductive layer 320. That is, the nitride semiconductor structure 317 has a planar lower surface along the X-direction and a convex upper surface along the Y-direction that extends from the planar lower surface in a direction away from the planar lower surface. In FIGS. 4A and 4B, the passivation pattern 330 surrounds the convex upper surface of the nitride semiconductor structure 317 in its entirety without surrounding the planar lower surface.

The light-emitting element 300 according to the fourth embodiment of the present disclosure may have a semispherical shape having a cross-sectional shape which is upwardly-convex. Accordingly, compared to the light-emitting element having a flat top surface, the light-emitting area may be increased and thus, light emission efficiency may be increased. Further, a spacing between the electrodes is smaller. Thus, the current injection may be easy, and thus, the resistance may be reduced.

Hereinafter, a method of forming light-emitting elements of various shapes having the above-described passivation patterns will be described.

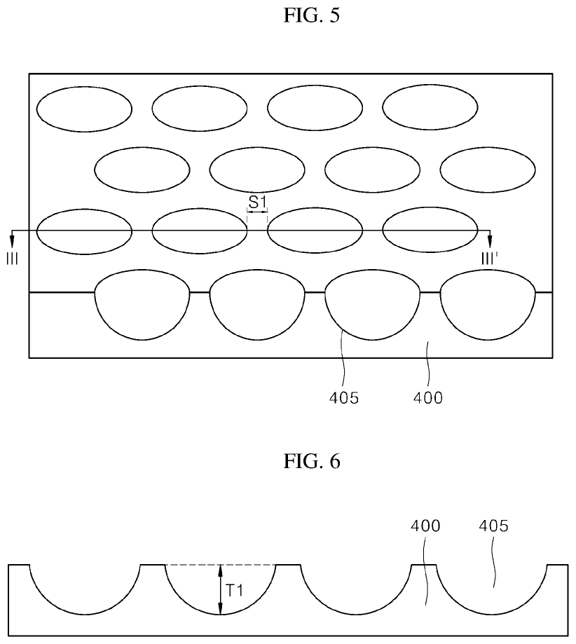

FIG. 5 to FIG. 14 are diagrams for illustrating a method for manufacturing the light-emitting element according to the second embodiment of the present disclosure. In this regard, FIG. 6 is a cross-sectional view of FIG. 5 cut along III-III′.

Referring to FIG. 5 and FIG. 6, a plurality of trenches 405 are formed in a growth substrate 400. To this end, a mask pattern having openings defined therein is formed on the growth substrate 400. Each opening defined in the mask pattern may expose a portion of a surface of the growth substrate 400 in an area where the trench 405 is to be formed. As shown in FIGS. 5 and 6, the trenches 405 have a concave shape. Subsequently, the plurality of trenches 405 are formed by etching the exposed portions of the growth substrate 400 using the mask pattern as an etch mask.

The growth substrate 400 may include a material such as sapphire, silicon (Si), silicon carbide (SiC) or gallium arsenide (GaAs). However, the present disclosure is not limited thereto. The trenches 405 positioned adjacent to each other may be arranged so as to be spaced apart from each other by a first distance S1.

The trench 405 may be formed in a concave shape having a first maximal depth T1 downwardly from the upper surface of the growth substrate 400. For example, the trench 405 may have a hemi-circular cross-sectional shape. As the trench 405 has a hemi-circular cross-sectional shape, the trench 405 may have the largest width at a top level thereof and may become gradually narrower as the trench extends downwardly towards a bottommost surface of the growth substrate 400.

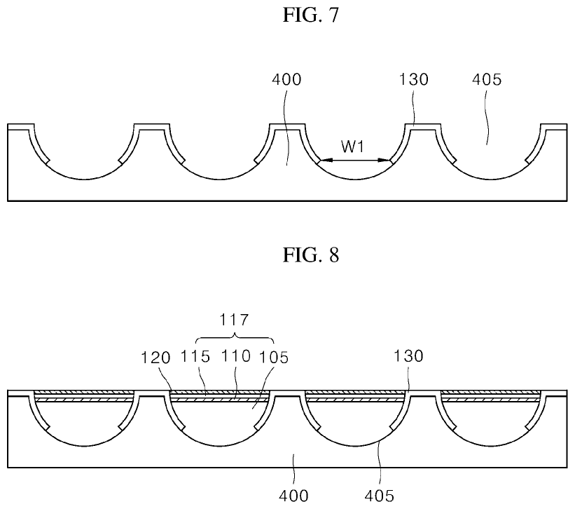

Referring to FIG. 7, the passivation pattern 130 is formed on an inner surface of each of the trenches 405 formed in the growth substrate 400. To this end, a passivation film is formed on an entirety of the surface of the growth substrate 400 having the trenches 405 formed therein. The passivation film may include an insulating material so as to prevent a nitride-based semiconductor from growing on the surface of the growth substrate. Next, a patterning process is performed on the passivation film to form the passivation pattern 130. The patterning process may be performed by forming a mask pattern having an opening defined therein exposing a portion of a surface of the passivation film and etching the exposed portion of the passivation film using the mask pattern as an etch mask. Thus, the passivation pattern is formed on the inner surface of the trench without completely covering the inner surface of the trench. The patterning process may be stopped at a point where the surface of the growth substrate 400 is exposed.

In this patterning process, the passivation pattern 130 selectively partially covering the inner surface of the trench 405 has been formed. The passivation pattern 130 may be formed along the inner surface of the trench 405 so as to expose a portion of the surface of the growth substrate 400 by a first width W1 in the trench 405. In one example, the exposed surface of growth substrate 400 may be a bottom surface of the trench 405. Further, the passivation pattern 130 covers a portion of an upper surface of the growth substrate 400 that is disposed between adjacent trenches 405.

Referring to FIG. 8, an epitaxy process is performed on the growth substrate 400 on which the passivation pattern 130 has been disposed. The epitaxial process may be understood as a process of growing a material in a specific orientation on a surface of a crystalline material. In order to form a light-emitting element structure of a micro-LED, a GaN-based compound semiconductor should be grown on the growth substrate 400. At this time, each layer is grown according to crystallinity of an underlying layer.

When the epitaxy process is performed, an inner space of the trench 405 where the passivation pattern 130 is not formed may be filled with the nitride semiconductor structure 117.

The passivation pattern 130 includes an insulating material on which a semiconductor layer cannot grow. Accordingly, a nitride semiconductor layer is grown from the portion of the surface of the growth substrate 400 not covered with the passivation pattern 130.

The nitride semiconductor structure 117 may have a structure in which the first semiconductor layer 105, the active layer 110, and the second semiconductor layer 115 are sequentially stacked on the bottom surface of the trench 405.

The first semiconductor layer 105 may grow from the exposed portion of the surface of the growth substrate 400 exposed through the trench 405 and may include a nitride semiconductor containing first conductivity-type impurities. For example, the first conductivity-type impurities may include N-type impurities. The nitride semiconductor may be made of the GaN-based semiconductor material including GaN, AlGaN, InGaN, or AlInGaN. The N-type impurities contained in the first semiconductor layer 105 may include silicon (Si), germanium (Ge), selenium (Se), or carbon ©.

The first semiconductor layer 105 may provide electrons to the active layer 110.

The active layer 110 may act as a layer for emitting light based on combination of electrons and holes, and may have a multi-quantum well (MQW) structure having a well layer and a barrier layer having a higher band gap than that of the well layer. For example, the active layer 110 may include an InGaN layer as the well layer and an AlGaN layer as the barrier layer.

The second semiconductor layer 115 is formed on the active layer 110. The second semiconductor layer 115 provides holes to the active layer 110. The second semiconductor layer 115 may be made of a nitride semiconductor containing second conductivity-type impurities. For example, the second conductivity-type impurities may include P-type impurities. The nitride semiconductor may be made of a GaN-based semiconductor material including GaN, AlGaN, InGaN, or AlInGaN. Manganese (Mg), zinc (Zn), or beryllium (Be) may be used as the P-type impurities used for doping of the second semiconductor layer 115.

In one example, in the present disclosure, an example in which the first semiconductor material layer 15 and the second semiconductor material layer 19 are made of the nitride semiconductor containing the N-type impurities and the nitride semiconductor including the P-type impurities, respectively is described. However, the present disclosure is not limited thereto. In another example, the first semiconductor material layer 105 and the second semiconductor material layer 115 may be made of a nitride semiconductor containing the P-type impurities and a nitride semiconductor containing the N-type impurities, respectively.

Subsequently, a conductive material layer is formed on the second semiconductor layer 115 and is patterned to form the conductive layer 120. An upper surface of the conductive layer 120 may be coplanar with an upper surface of the passivation pattern 130. The conductive layer 120 may be formed of a single layer or multiple layers made of a conductive material such as titanium (Ti), chromium (Cr), aluminum (Al), or gold (Au). In another example, the conductive layer 120 may include a transparent metal oxide such as indium-tin-oxide (ITO), or indium-zinc-oxide (IZO). In still another example, the conductive layer 120 may include a material having magnetism.

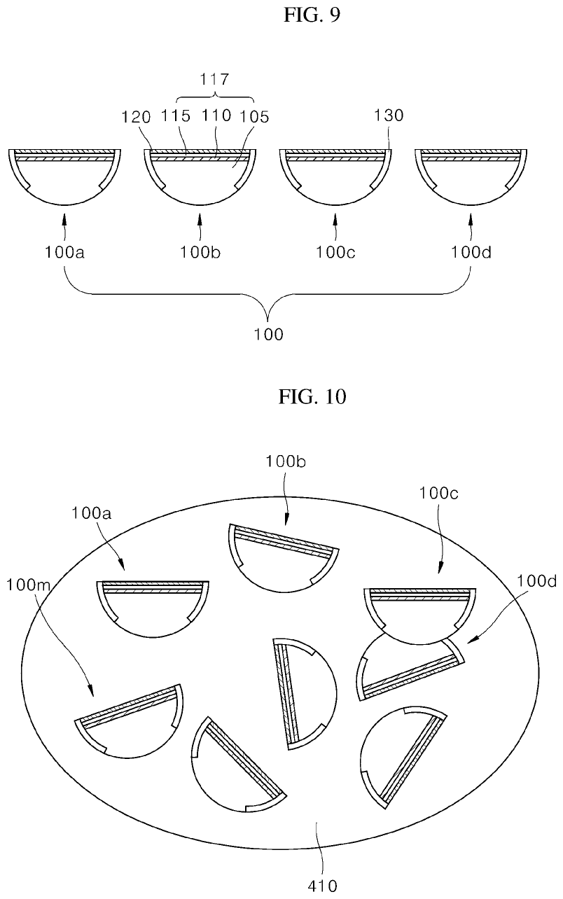

Referring to FIG. 9, the light-emitting element 100 is manufactured by removing the growth substrate 400 from the nitride semiconductor structure 117 including the conductive layer 120. The light emitting element 100 may be understood includes the shape of the light emitting element 100 described in FIG. 2B. The light-emitting element 100 may be separated into individual light-emitting elements 100a, 100b, 100c, and 100d. The growth substrate 400 may be removed therefrom in the laser lift-off (LLO) manner. The individual light-emitting elements 100a, 100b, 100c, and 100d obtained in this way may be then transferred to a package substrate. One light-emitting element constitutes one sub-pixel.

In one example, the light-emitting element according to the present disclosure is formed by performing an epitaxial growth process in a state in which the active layer 110 is covered with the passivation pattern 130, and a shape of the light-emitting element is pre-formed using the trench 405 (see FIG. 5). Thus, the dry etching process using plasma may be omitted. This may prevent the active layer 110 from being damaged by the plasma such that the abnormal combination of electrons and holes that does not participate in light emission may be suppressed. Thus, the decrease in light-emitting efficiency due to the decrease in the light-emitting area may be prevented.

Next, referring to FIG. 10 to FIG. 13, an alignment process of supplying and aligning the separated light-emitting elements 100a, 100b, 100c, and 100d on the package substrate is performed.

To this end, first, referring to FIG. 10, a plurality of separated light-emitting elements 100a, 100b, 100c, 1© . . . 100m, (m is a natural number) is dispersed in a transfer solution 410. The light-emitting elements 100a, 100b, 100c, 100d . . . 100m are contained irregularly in the transfer solution 410. The transfer solution 410 may include heat-sensitive or photo-sensitive volatile material volatilized under exposed to light or heat. In another example, the light-emitting elements 100a, 100b, 100c, 100d . . . 100m may be dispersed in transfer ink.

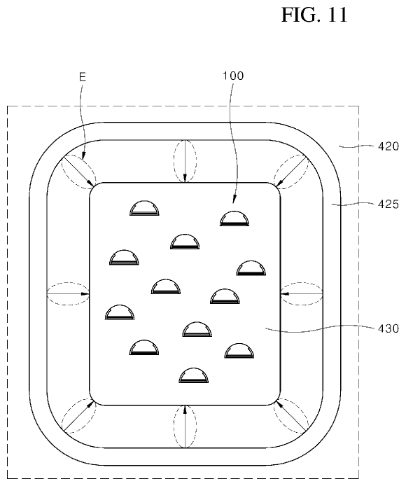

Referring next to FIG. 11, the transfer solution 410 in which the plurality of light-emitting elements 100a, 100b, 100c, 100d . . . 100m is dispersed is supplied to a position of the package substrate 420 at which a pixel is to be formed using an inkjet scheme or a dispensing scheme.

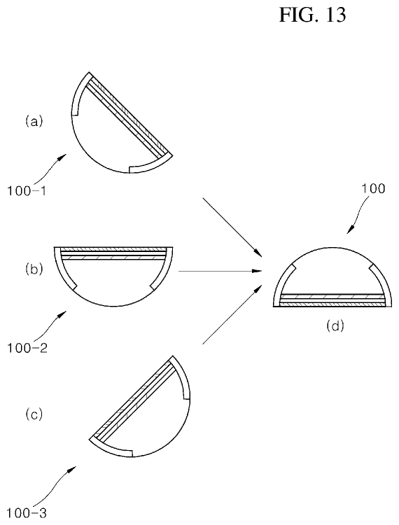

Each of the plurality of light-emitting elements 100a, 100b, 100c, 100d . . . 100m disposed on the package substrate 420 may be oriented irregularly. For example, referring to FIG. 13, the light-emitting element 100 may emit light normally only when the light-emitting element 100 is oriented at a first orientation (d) in which a convex surface thereof faces upwardly, and a flat surface thereof at which the conductive layer 120 is positioned faces downwardly. However, immediately after being supplied on the package substrate 420, the light-emitting element 100-1 may be oriented at a second orientation (a) in which the light-emitting element 100-1 is tilted in one direction, the light-emitting element 100-2 may be oriented at a third orientation (b) in which a convex surface thereof faces downwardly, and a flat surface thereof at which the conductive layer 120 is positioned faces upwardly, or the light-emitting element 100-3 may be oriented at a fourth orientation (c) in which the light-emitting element 100-3 is tilted in the opposite direction to the direction in the second orientation (a).

Accordingly, an alignment process for aligning the light-emitting elements having various orientations so as to have the first orientation (d) is required.

A first electrode 430 may be pre-disposed on the package substrate 420. Further, a power supply electrode 425 may be disposed adjacent to the first electrode 430. In one example, the first electrode 430 may include a transparent metal oxide such as indium-tin-oxide (ITO) or indium-zinc-oxide (IZO). The first electrode 430 may be referred to as an anode electrode or a pixel electrode.

When electric power is continuously applied between the power supply electrode 425 and the first electrode 430, an electric field E at a constant wavelength is generated so that a plurality of light-emitting elements may be oriented at the first orientation (d) (see FIG. 13). For example, the first semiconductor layer 105 and the second semiconductor layer 115 of the light-emitting element 100 have different dielectric constants. When AC power is applied between the power supply electrode 425 and the first electrode 430, the light-emitting element 100 may rotate in one direction due to the difference between the dielectric constants of the first semiconductor layer 105 and the second semiconductor layer 115. In other words, the light-emitting elements may be oriented to have the first orientation (d) due to the difference between the dielectric constants of the first semiconductor layer 105 and the second semiconductor layer 115.

However, when the light-emitting element has only a flat surface, it may be difficult for the light-emitting element to rotate in one direction or be displaced. In contrast thereto, the light-emitting element 100 according to the embodiment of the present disclosure has a hemispherical shape, it is easy for the light-emitting element 100 to rotate in one direction or to be displaced, or to flip-over or to be turned upside down. Accordingly, as shown in FIG. 13, even when the light-emitting elements 100-1, 100-2, and 100-3 are oriented at the second, third, and fourth orientations (a), (b), and (c), respectively, the orientation of the light-emitting elements 100-1, 100-2, and 100-3 may be easily changed to the correct orientation, that is, the first orientation (d) under the electric field.

In another example, even when the conductive layer 120 includes a material having magnetism, alignment may be performed in a direction parallel to a flat surface on which the conductive layer 120 having the magnetism is positioned.

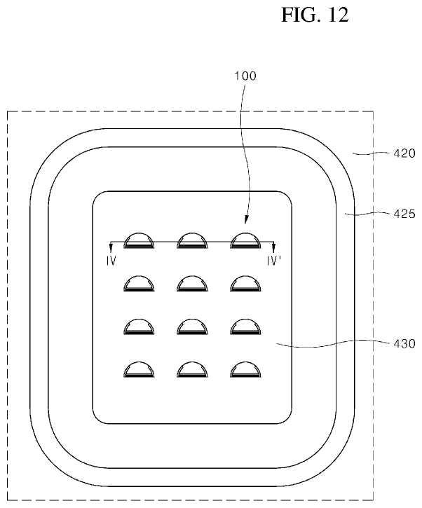

When the alignment process has been completed, the plurality of light-emitting elements 100 may be aligned on the first electrode 430 as shown in FIG. 12. Then, light or heat may be applied to the transfer solution 410 to remove the transfer solution 410 (see FIG. 10).

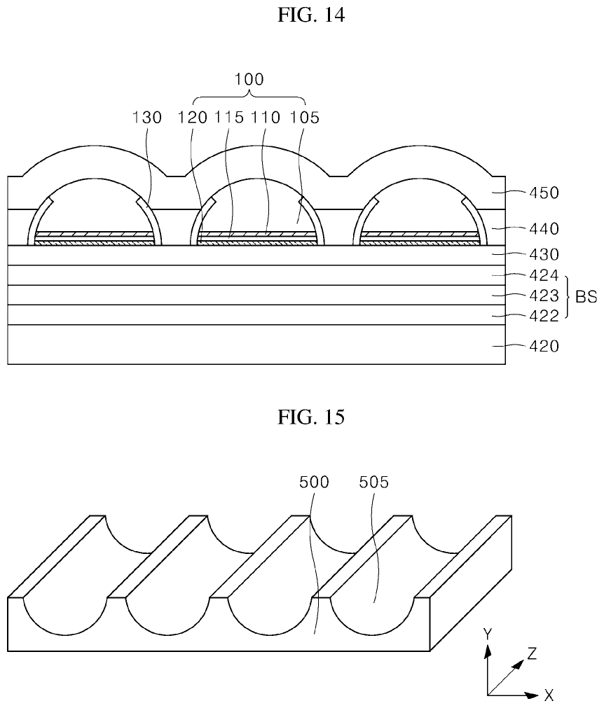

Referring to FIG. 14, a planarization film 440 and a second electrode 450 are formed on the first electrode 430 on which the light-emitting elements 100 are aligned.

The planarization film 440 may have a sufficient thickness to serve to protect underlying elements and to fill a space between the adjacent light-emitting elements 100 to reduce a step amount. The planarization film 440 may include an organic or inorganic insulating material. The planarization film 440 may be formed to surround a side surface of the passivation pattern 130 of the light-emitting element 100. The planarization film 440 may be formed to have a height equal to or smaller than that of the passivation pattern 130 such that a portion of a surface of the first semiconductor layer 105 as a topmost layer of the light-emitting element 100 is exposed.

The second electrode 450 may be formed so as to contact the first semiconductor layer 105 of the light-emitting element 100. The second electrode 450 may commonly contact the adjacent light-emitting elements 100 and may apply a voltage thereto. The second electrode 450 may be referred to as a cathode electrode or a common electrode. The second electrode 450 may include a transparent metal oxide such as indium-tin-oxide (ITO) or indium-zinc-oxide (IZO).

A lower structure BS may be disposed on top of the package substrate 420 and may be disposed under the first electrode 430. The lower structure BS may include a buffer layer 422, a metal line 423, and a protective layer 424.

Since the light-emitting element according to the first embodiment of the present disclosure has the hemispherical shape with one surface which is flat and the other surface opposite thereto which is convex, the light-emitting element may be easily turned upside down in a process for aligning the light-emitting elements on the package substrate. Further, as the light-emitting element has the upwardly-convex hemispherical shape, the light-emitting area size may be relatively larger and thus the light emission efficiency may be increased, compared to the light-emitting element having a flat top surface. Further, one surface of the conductive layer of the light-emitting element which contacts the first electrode is flat. Thus, electrical connection between the conductive layer and the first electrode is reliable. Further, the conductive layer of the light-emitting element contacts the first electrode, and the second electrode is disposed on a top face of the first semiconductor layer of the light-emitting element, such that the first and second electrodes for driving the light-emitting element are arranged in a vertical manner Thus, it may be easy to construct a sub-pixel including the light-emitting element. Thus, manufacturing process efficiency may be improved.

In addition, a frame for forming the light-emitting element may be pre-formed and then the light-emitting element may be formed using the pre-formed frame in the epitaxial growth scheme. Thus, the etching process may be omitted, so that damage to the side surface of the nitride semiconductor layer may be prevented. Accordingly, dislocation that may occur on the nitride semiconductor layer in the process of performing the etching process may be reduced, thereby increasing the efficiency of the light-emitting element.

FIG. 15 to FIG. 19 are diagrams for illustrating a method for manufacturing the light-emitting element according to the third embodiment of the present disclosure.

Referring to FIG. 15, a plurality of trenches 505 are formed in the growth substrate 500. The trenches 505 positioned adjacent to each other may be spaced apart from each other. The trench 505 may be formed to have a concave shape having a first maximal depth in a Y-axis direction inwardly from the surface of a growth substrate 500. In addition, the trench 505 may be formed to have a first length in a Z-axis direction as a length direction of the growth substrate 500. The trench may have a semi-cylindrical shape. A ratio of the maximal depth and the length of the trench 505 may be in a range of 1:1 to 1:10.

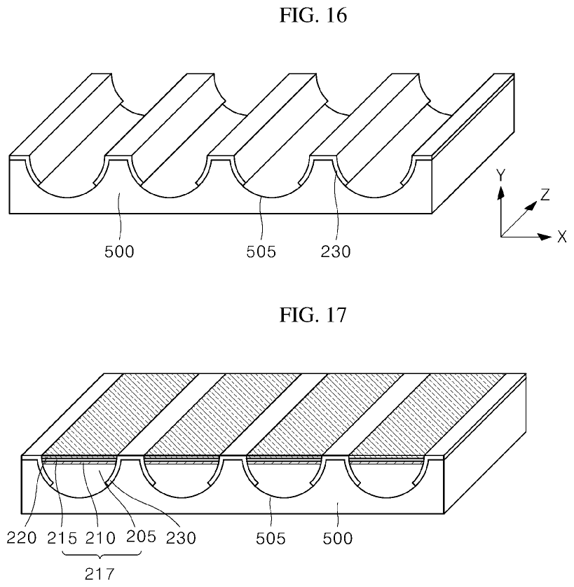

Referring to FIG. 16, a passivation pattern 230 is formed on an inner surface of each of the plurality of trenches 505 formed in the growth substrate 500. To this end, a passivation film is formed on an entirety of the surface of the growth substrate 500 having the trenches 505 formed therein. The passivation film may include an insulating material so as to prevent a nitride-based semiconductor from growing on the surface of the growth substrate. Next, a patterning process is performed on the passivation film to form the passivation pattern 230. The patterning process may be performed by forming a mask pattern having an opening defined therein exposing a portion of a surface of the passivation film and etching the exposed portion of the passivation film using the mask pattern as an etch mask. The patterning process may be stopped at a point where the surface of the growth substrate 500 is exposed.

In this patterning process, the passivation pattern 230 selectively partially covering the inner surface of the trench 505 has been formed. The passivation pattern 230 may extend in the Z-axis direction as the length direction of the trench 505, and may be formed along the inner surface of the trench 505 so as to expose a portion of the surface of the growth substrate 500 by a predefined width in the trench 505. In one example, the exposed surface of growth substrate 500 may be a convex bottom surface of the trench 505. Further, the passivation pattern 230 covers a portion of an upper surface of the growth substrate 500 that is disposed between adjacent trenches 505.

Referring to FIG. 17, an epitaxy process is performed on the growth substrate 500 on which the passivation pattern 230 has been disposed. The epitaxial process may be understood as a process of growing a material in a specific orientation on a surface of a crystalline material. In order to form a light-emitting element structure of a micro-LED, a GaN-based compound semiconductor should be grown on the growth substrate. At this time, each layer is grown according to crystallinity of an underlying layer.

When the epitaxy process is performed, an inner space of the trench 505 where the passivation pattern 230 is not formed may be filled with the nitride semiconductor structure 217. The passivation pattern 230 includes an insulating material on which a semiconductor layer cannot grow. Accordingly, a nitride semiconductor layer is grown from the portion of the surface of the growth substrate 500 not covered with the passivation pattern 230.

The nitride semiconductor structure 217 may have a structure in which the first semiconductor layer 205, the active layer 210, and the second semiconductor layer 215 are sequentially stacked on the bottom surface of the trench 505.

The first semiconductor layer 205 may grow from the exposed portion of the surface of the growth substrate 500 exposed through the trench 505 and may include a nitride semiconductor containing first conductivity-type impurities. For example, the first conductivity-type impurities may include N-type impurities. The nitride semiconductor may be made of the GaN-based semiconductor material including GaN, AlGaN, InGaN, or AlInGaN. The N-type impurities contained in the first semiconductor layer 205 may include silicon (Si), germanium (Ge), selenium (Se), or carbon (C). The first semiconductor layer 205 may provide electrons to the active layer 210.

The active layer 210 may act as a layer for emitting light based on combination of electrons and holes, and may have a multi-quantum well (MQW) structure having a well layer and a barrier layer having a higher band gap than that of the well layer. For example, the active layer 210 may include an InGaN layer as the well layer and an AlGaN layer as the barrier layer.

The second semiconductor layer 215 is formed on the active layer 210. The second semiconductor layer 215 provides holes to the active layer 210. The second semiconductor layer 215 may be made of a nitride semiconductor containing second conductivity-type impurities. For example, the second conductivity-type impurities may include P-type impurities. The nitride semiconductor may be made of a GaN-based semiconductor material including GaN, AlGaN, InGaN, or AlInGaN. Manganese (Mg), zinc (Zn), or beryllium (Be) may be used as the P-type impurities used for doping of the second semiconductor layer 215.

In one example, in the present disclosure, an example in which the first semiconductor material layer 15 and the second semiconductor material layer 19 are made of the nitride semiconductor containing the N-type impurities and the nitride semiconductor including the P-type impurities, respectively is described. However, the present disclosure is not limited thereto. In another example, the first semiconductor material layer 15 and the second semiconductor material layer 19 may be made of a nitride semiconductor containing the P-type impurities and a nitride semiconductor containing the N-type impurities, respectively.

Subsequently, a conductive material layer is formed on the second semiconductor layer 215 so as to contact one surface of the second semiconductor layer 215, and is patterned to form the conductive layer 220 contacting one surface of the second semiconductor layer 215. An upper surface of the conductive layer 220 may be coplanar with an upper surface of the passivation pattern 230. The conductive layer 220 may be formed of a single layer or multiple layers made of a conductive material such as titanium (Ti), chromium (Cr), aluminum (Al), or gold (Au). In another example, the conductive layer 220 may include a transparent metal oxide such as indium-tin-oxide (ITO), or indium-zinc-oxide (IZO). In still another example, the conductive layer 220 may include a material having magnetism.

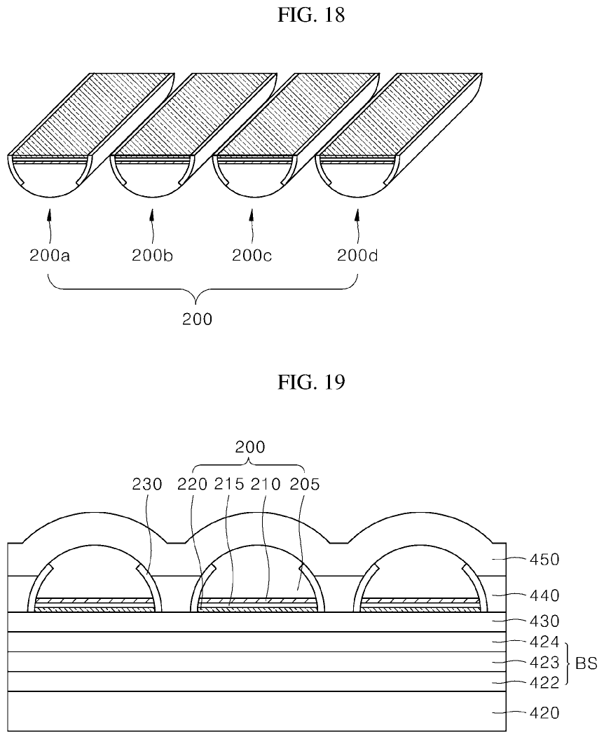

Referring to FIG. 18, the light-emitting element 200 is manufactured by removing the growth substrate 500 from the nitride semiconductor structure 217 including the conductive layer 220. The light-emitting element 200 may be separated into individual light-emitting elements 200a, 200b, 200c, and 200d. The growth substrate 500 may be removed therefrom in the laser lift-off (LLO) manner. The individual light-emitting elements 200a, 200b, 200c, and 200d obtained in this way may be then transferred to a package substrate. One light-emitting element constitutes one sub-pixel.

In one example, the light-emitting element according to the present disclosure is formed by performing an epitaxial growth process in a state in which a shape of the light-emitting element is pre-formed using the trench 505. Thus, the dry etching process using plasma may be omitted. This may prevent the active layer 210 from being damaged by the plasma such that the abnormal combination of electrons and holes that does not participate in light emission may be suppressed. Thus, the decrease in light-emitting efficiency due to the decrease in the light-emitting area may be prevented.

Then, an alignment process of supplying and aligning the separated light-emitting elements 200a, 200b, 200c, and 200d on the package substrate is performed.

To this end, first, a plurality of separated light-emitting elements 200a, 200b, 2©, 200d . . . 200m, (m is a natural number) is dispersed in a transfer solution. The light-emitting elements 200a, 200b, 200c, 200d . . . 200m are contained irregularly in the transfer solution 410. The transfer solution may include heat-sensitive or photo-sensitive volatile material volatilized under exposed to light or heat. In another example, the light-emitting elements 200a, 200b, 200c, 200d . . . 200m may be dispersed in transfer ink.

Then, the transfer solution in which the plurality of light-emitting elements 200a, 200b, 200c, 200d . . . 200m is dispersed is supplied to a position of the package substrate 420 at which a pixel is to be formed using an inkjet scheme or a dispensing scheme. Each of the plurality of light-emitting elements 200a, 200b, 200c, 200d . . . 200m disposed on the package substrate 420 may be oriented irregularly.

The first electrode 430 may be pre-disposed on the package substrate 420. Further, the power supply electrode 425 may be disposed adjacent to the first electrode 430. In one example, the first electrode 430 may include a transparent metal oxide such as indium-tin-oxide (ITO) or indium-zinc-oxide (IZO). The first electrode 430 may be referred to as an anode electrode or a pixel electrode. When electric power is continuously applied between the power supply electrode 425 and the first electrode 430, an electric field E at a constant wavelength is generated so that a plurality of light-emitting elements may be oriented at the correct orientation as shown in FIG. 13. For example, the first semiconductor layer 205 and the second semiconductor layer 215 of the light-emitting element 200 have different dielectric constants. When AC power is applied between the power supply electrode 425 and the first electrode 430, the light-emitting element 200 may rotate in one direction due to the difference between the dielectric constants of the first semiconductor layer 205 and the second semiconductor layer 215. In other words, the light-emitting elements may be oriented to have the correct orientation due to the difference between the dielectric constants of the first semiconductor layer 205 and the second semiconductor layer 215.

However, when the light-emitting element has only a flat surface, it may be difficult for the light-emitting element to rotate in one direction or be displaced. In contrast thereto, the light-emitting element 200 according to the embodiment of the present disclosure has the semi-cylindrical shape, it is easy for the light-emitting element 200 to rotate in one direction or to be displaced, or to flip-over or to be turned upside down. Thus, the orientation of the light-emitting elements may be easily changed to the correct orientation under the electric field.

When the alignment process has been completed, the plurality of light-emitting elements 200 may be aligned on the first electrode 430. Then, light or heat may be applied to the transfer solution to remove the transfer solution.

Then, the planarization film 440 and the second electrode 450 are formed on the first electrode 430 on which the light-emitting elements 200 are disposed. The planarization film 440 may have a sufficient thickness to serve to protect underlying elements and to fill a space between the adjacent light-emitting elements 200 to reduce a step amount. The planarization film 440 may include an organic or inorganic insulating material. The planarization film 440 may be formed to surround a side surface of the passivation pattern 230 of the light-emitting element 200. The planarization film 440 may be formed to have a height equal to or smaller than that of the passivation pattern 230 such that a portion of a surface of the first semiconductor layer 205 as a topmost layer of the light-emitting element 200 is exposed.

The second electrode 450 may be formed so as to contact the first semiconductor layer 205 of the light-emitting element 200. The second electrode 450 may commonly contact the adjacent light-emitting elements 200 and may apply a voltage thereto. The second electrode 450 may be referred to as a cathode electrode or a common electrode. The second electrode 450 may include a transparent metal oxide such as indium-tin-oxide (ITO) or indium-zinc-oxide (IZO).

The lower structure BS may be disposed on top of the package substrate 420 and may be disposed under the first electrode 430. The lower structure BS may include the buffer layer 422, the metal line 423, and the protective layer 424. Thus, the display device as shown in FIG. 19 may be manufactured.

Since the light-emitting element according to the second embodiment of the present disclosure has the semi-cylindrical shape extending in the length direction, and having one surface which is flat and the other surface opposite thereto which is convex, the light-emitting element may be easily turned upside down in a process for aligning the light-emitting elements on the package substrate. Further, as the light-emitting element has the upwardly-convex top surface, the light-emitting area size may be relatively larger and thus the light emission efficiency may be increased and light extraction may be easy, compared to the light-emitting element having the flat top surface. Further, one surface of the conductive layer of the light-emitting element which contacts the first electrode is flat. Thus, electrical connection between the conductive layer and the first electrode is reliable. One surface of the conductive layer of the light-emitting element contacts the first electrode, and the second electrode is disposed on a top face of the first semiconductor layer of the light-emitting element, such that the first and second electrodes for driving the light-emitting element are arranged in a vertical manner Thus, it may be easy to construct the sub-pixel including the light-emitting element. Thus, manufacturing process efficiency may be improved.

In addition, a frame for forming the light-emitting element may be pre-formed and then the light-emitting element may be formed using the pre-formed frame in the epitaxial growth scheme. Thus, the etching process may be omitted, so that damage to the side surface of the nitride semiconductor layer may be prevented. Accordingly, dislocation that may occur on the nitride semiconductor layer in the process of performing the etching process may be reduced, thereby increasing the efficiency of the light-emitting element.

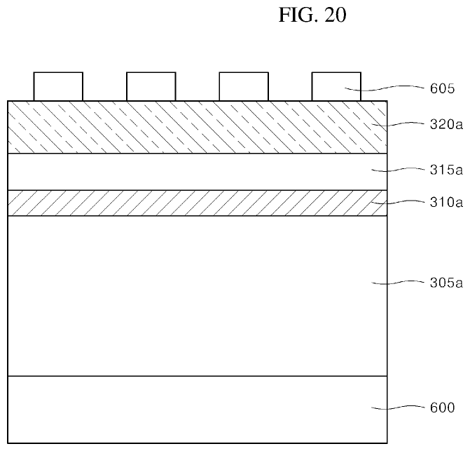

FIG. 20 to FIG. 30 are diagrams for illustrating a method for manufacturing the light-emitting element according to the fourth embodiment of the present disclosure.

Referring to FIG. 20, a stack structure in which a first semiconductor material layer 305a, an active material layer 310a, a second semiconductor material layer 315a, and a first electrode material layer 320a are sequentially stacked is disposed on a growth substrate 600.

The first semiconductor material layer 305a may be made of a nitride semiconductor containing first conductivity-type impurities, for example, N-type impurities. The N-type impurities contained in the first semiconductor material layer 305a may include silicon (Si), germanium (Ge), selenium (Se)©r carbon (C).

The active material layer 310a may be a layer for emitting light based on combination of electrons and holes, and may have a multi-quantum well (MQW) structure.

The second semiconductor material layer 315a may be made of a nitride semiconductor containing second conductivity-type impurities. For example, the second conductivity-type impurities may include P-type impurities. The nitride semiconductor may be made of a GaN-based semiconductor material including GaN, AlGaN, InGaN, or AlInGaN. Manganese (Mg), zinc (Zn), or beryllium (Be) may be used as the P-type impurities.

The first electrode material layer 320a may be composed of a single layer or multiple layers made of a conductive material such as titanium (Ti), chromium (Cr), aluminum (Al), or gold (Au). Alternatively, the first electrode material layer 320a may be made of a transparent metal oxide such as indium-tin-oxide (ITO) or indium-zinc-oxide (IZO).

Next, a mask pattern 605 having a plurality of openings defined therein arranged so as to be spaced from each other by an equal spacing is formed on the first electrode material layer 320a. Subsequently, using the mask pattern 605, a portion of each of the first electrode material layer 320a, the second semiconductor material layer 315a, the active material layer 310a, and the first semiconductor material layer 305a in an area exposed through the opening is etched away until the surface of the growth substrate 600 is exposed. The etching using the mask pattern 605 may be performed using a dry etching scheme.

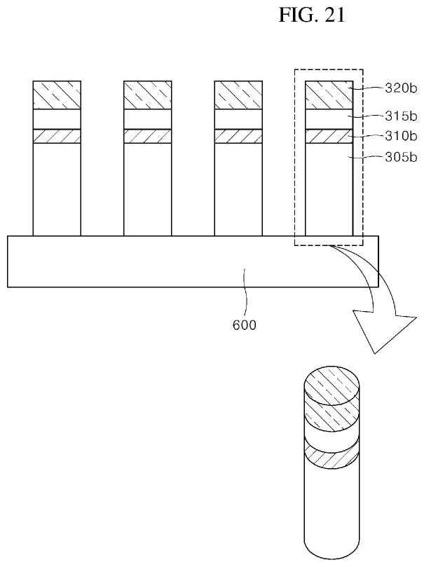

Thus, as shown in FIG. 21, a stack structure in which a pre-first semiconductor layer 305b, a pre-active layer 310b, a pre-second semiconductor layer 315b, and a pre-conductive layer 320b are stacked may be formed on the growth substrate 600. The stack structures are arranged so as to be spaced from each other. Referring to an enlarged view of one of the stack structures, the stack structure may have a nano-rod shape like a cylinder.

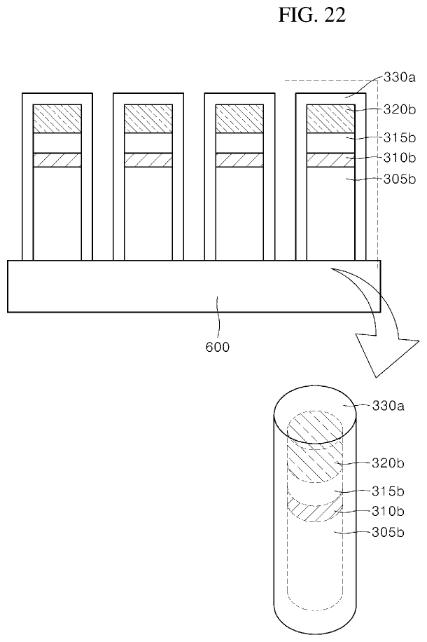

Referring to FIG. 22, a pre-passivation layer 330a is formed on the stack structure. The pre-passivation layer 330a may include an insulating material. As shown in an enlarged view of one of the stack structures, the pre-passivation layer 330a may be formed to cover an entirety of an outer surface of the stack structure.

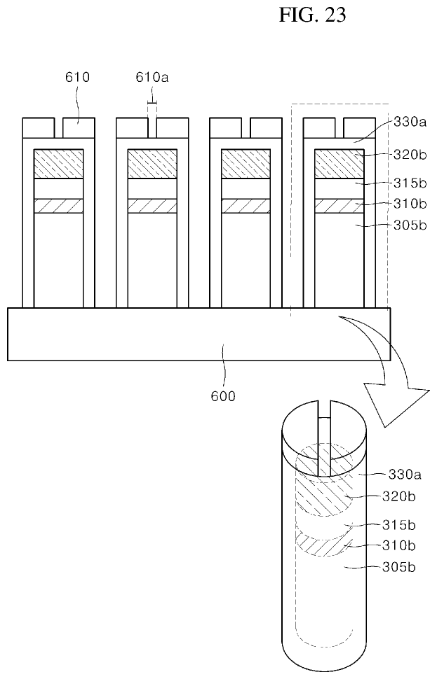

Referring to FIG. 23, a mask pattern 610 having an opening 610a defined therein is formed on the pre-passivation layer 330a. The mask pattern 610 may be divided into two portions spaced from each other via the opening 610a having a first width such that the two portions may be respectively disposed on both opposing sides of a top surface of the stack structure. In this regard, each of the two portions of the mask pattern 610 may be formed to have a semicircular shape, as shown in an enlarged view of one of the stack structures. However, the present disclosure is not limited thereto.

Next, an etching process of downwardly etching the pre-passivation layer 330a and the stack structure in an area exposed through the opening 610a using the mask pattern 610 as an etch mask is performed. The etching process may be performed in a dry etching scheme. After the etching process has been finished, the mask pattern 610 is removed.

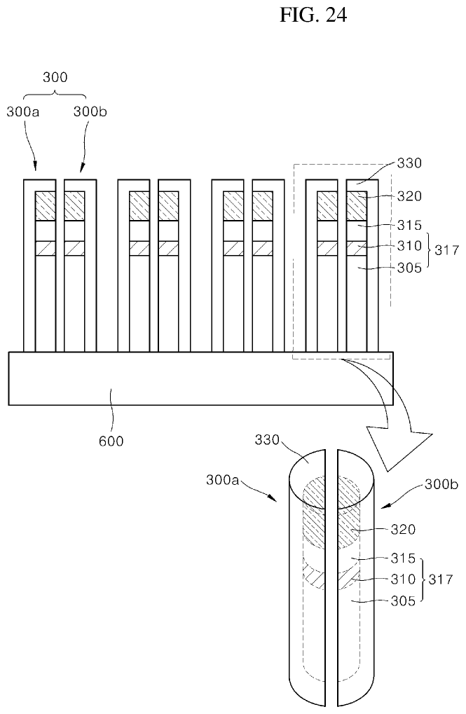

Thus, as shown in FIG. 24, one stack structure is etched in the area not covered with the mask pattern 610, such that one stack structure may be separated into two light-emitting elements 300a and 300b. The passivation pattern 330 covers an outer surface of each of the light-emitting elements 300a and 300b.

One stack structure having the cylindrical shape is separated into the two light-emitting elements 300a and 300b, such that each of the light-emitting elements 300a and 300b may be formed in the semi-cylindrical shape. Accordingly, a cross-sectional shape of each of the light-emitting elements 300a and 300b may have a semi-circular shape. One side surface of each of the light-emitting elements 300a and 300b may be convex, while the other side surface thereof opposite thereto may be flat.

Each of the light-emitting elements 300a and 300b may include the nitride semiconductor structure 317, the conductive layer 320 positioned on one surface of the nitride semiconductor structure 317, and the passivation pattern 330. The nitride semiconductor structure 317 may include the first semiconductor layer 305, the active layer 310, and the second semiconductor layer 315.

The passivation pattern 330 may cover the convex side surface of the semi-cylindrical shape and may not cover the flat side surface thereof opposite thereto so as to be exposed.

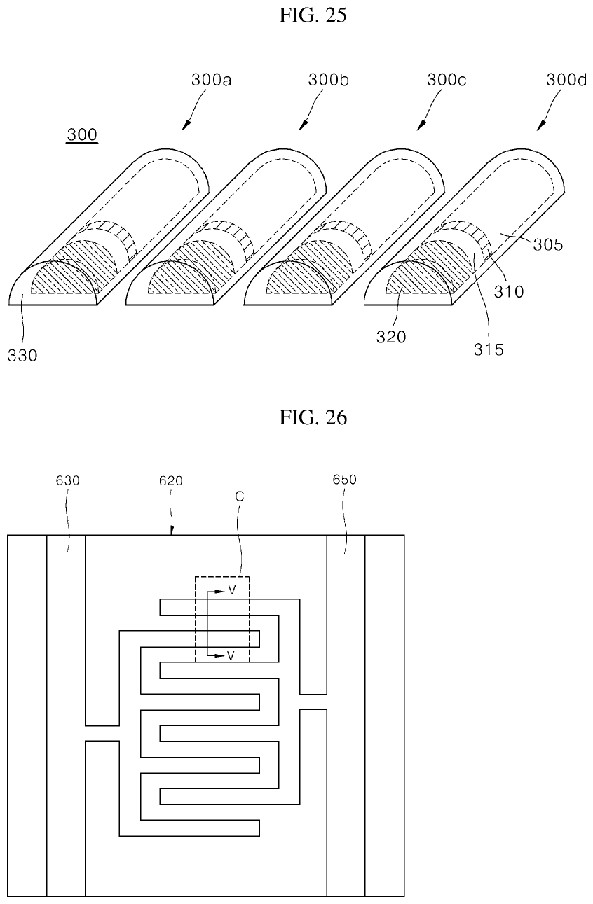

Referring to FIG. 25, the growth substrate 600 is removed from the light-emitting elements 300a and 300b such that individual light-emitting elements 300a, 300b, 300c and 300d are obtained in a separated manner. In this case, the growth substrate 600 may be removed in the laser lift off (LLO) manner. The individual light-emitting elements 300a, 300b, 300c, and 300d obtained in the separated manner are then transferred to the package substrate. One light-emitting element constitutes one sub-pixel.

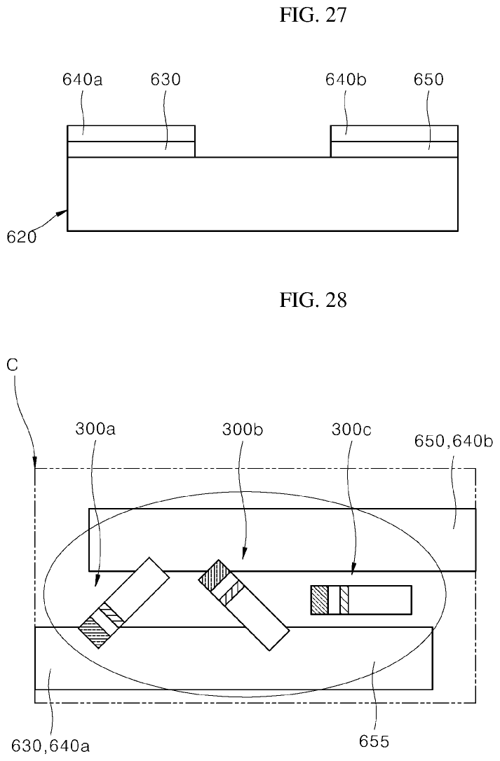

Referring to FIG. 26 and FIG. 27, a package substrate 620 on which the separated light-emitting elements 300a, 300b, 300c, and 300d are placed is prepared. Line electrodes 630 and 650 may be disposed on the package substrate 620.

Referring to FIG. 27 as an enlarged cross-sectional view of an area C of FIG. 26 cut along a V-V′ line, the line electrodes 630 and 650 may include the first electrode 630 and the second electrode 650.

The first electrode 630 and the second electrode 650 may be positioned on the package substrate 620 and may be disposed in the same layer. The second electrode 650 may be spaced apart from the first electrode 630 by a predetermined distance. The first electrode 630 and the second electrode 650 may be made of the same material and may be formed in the same process. Accordingly, each of a deposition process and an etching process for forming the first electrode 630 and the second electrode 650 may be performed only one time. However, when the first electrode 630 and the second electrode 650 are arranged in the vertical direction, each of the deposition process and the etching process is required to be performed at least twice to form the first electrode 630 and the second electrode 650. Thus, the number of process steps may be increased. Therefore, according to the fourth embodiment of the present disclosure, the number of the processes for forming the first and second electrodes 630 and 650 may be reduced, and thus, the manufacturing process may be simplified.

In one example, each of the first electrode 630 and the second electrode 650 may include a transparent metal oxide such as indium-tin-oxide (ITO) or indium-zinc-oxide (IZO). The first electrode 630 may be referred to as an anode electrode or a pixel electrode. The second electrode 650 may be referred to as a cathode electrode or a common electrode.

Connection electrodes 640a and 640b are formed on the first electrode 630 and the second electrode 650, respectively. The connection electrodes 640a and 640b serve to connect the light-emitting element to the first electrode 630 and the second electrode 650, respectively. The connection electrodes 640a and 640b may include the first connection electrode 640a positioned on the first electrode 630 and the second connection electrode 640b positioned on the second electrode 650. Each of the first and second connection electrodes 640a and 640b may include a conductive metal material alloy or an anisotropic conductive film (ACF).

Next, an alignment process of supplying the separated light-emitting elements 300a, 300b, and 300c on the package substrate 620 and aligning the separated light-emitting elements 300a, 300b, and 300c on the line electrodes 630 and 650 is performed.

To this end, the separated light-emitting elements 300a, 300b, and 300c are first dispersed in a transfer solution 655. The transfer solution may include a heat-sensitive or photo-sensitive volatile material that can be volatilized under exposure to light or heat. In another example, the light-emitting elements 300a, 300b, 300c may be dispersed in the transfer ink.

Next, as shown in FIG. 28, the transfer solution 655 in which the light-emitting elements 300a, 300b, and 300c are dispersed is applied on the line electrodes 630 and 650 of the package substrate 620 using a dispensing scheme such as an inkjet scheme. Then, power is applied to the line electrodes 630 and 650 to align and orient the light-emitting elements 300a, 300b, and 300c.

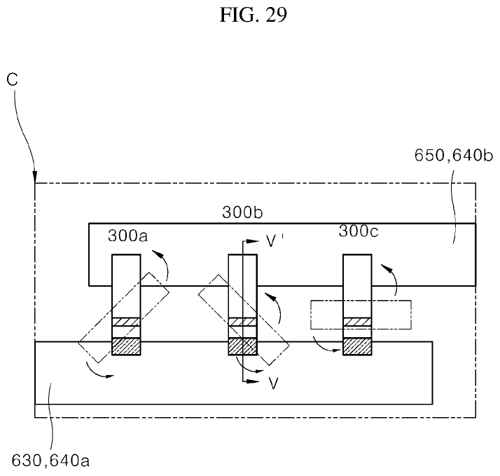

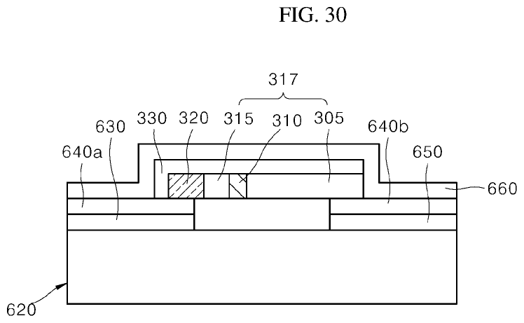

FIG. 29 is a view showing a state in which the light-emitting elements 300a, 300b, and 300c are aligned and oriented on the line electrodes 630 and 650. FIG. 30 is a cross-sectional view of one light-emitting element among the light-emitting elements of FIG. 29 as cut along a V-V line. Referring to FIGS. 29 and 30, when the power is applied to the light-emitting elements 300a, 300b, and 300c, the light-emitting elements 300a, 300b, and 300c may rotate so as to be aligned as indicated by an arrow. In this regard, each of the aligned light-emitting elements 300a, 300b, and 300c may have one end positioned on the first connection electrode 640a connected to the first electrode 630, and the other end positioned on the second connection electrode 640b connected to the second electrode 650.

Each of the light-emitting elements may have a semi-cylindrical shape with one side surface being convex and the other side surface opposite thereto and being flat. In addition, the flat side surface of each of the light-emitting elements aligned on the package substrate 620 which is not covered with the passivation pattern 330 can contact the first and second connection electrodes 640a and 640b.

A protective layer 660 is formed on the first and second connection electrodes 640a and 640b and the light-emitting element in contact with the first and second connection electrodes 640a and 640b which have been disposed on the package substrate 620. The protective layer 660 may protect one side surface of the first semiconductor layer 305 that is not covered with the passivation pattern 330. The protective layer 660 may include an insulating material.

Further, the first electrode 630 and the second electrode 650 may be electrically connected to a bottom of the light-emitting element via the first connection electrode 640a and the second connection electrode 640b, respectively. Accordingly, a distance by which the current supplied from the first electrode 630 is injected to the light-emitting element is equal to a thickness of the first connection electrode 640a. A distance by which the current supplied from the second electrode 650 is injected to the light-emitting element direction is equal to a thickness of the second connection electrode 640b. In other words, a distance by which carriers including electrons or holes migrate can be reduced to about the thickness of the first connection electrode 640a or the second connection electrode 640b. When the distance by which the carriers migrate increases, electrical resistance may increase during the migration. Accordingly, easy current injection may be achieved to lower the electrical resistance.

The light-emitting element according to the present disclosure has the semi-cylindrical shape having the convex side surface and the opposite and flat side surface. Accordingly, even when the light-emitting elements 300a, 300b, and 300c are placed on the package substrate 620 in an upside-down state, the light-emitting elements 300a, 300b, and 300c may be easily turned upside down so as to have the correct orientation in the alignment process. Thus, the alignment process may be achieved in an easy manner.

Further, the first electrode and the second electrode as driving electrodes for driving the light-emitting element are positioned in the same layer while being disposed under the light-emitting element. In other words, the first electrode and the second electrode may be formed in the same process. Accordingly, the number of the deposition processes for forming the first electrode and the second electrode may be reduced, thereby simplifying the manufacturing process of the display device. Further, as the first electrode and the second electrode are disposed under the light-emitting element, a spacing between the electrodes may be reduced. Accordingly, easy current injection may be achieved to lower the electrical resistance.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What claimed is:

1. A light-emitting device comprising:
a nitride semiconductor structure including a first semiconductor layer, an active layer on the first semiconductor layer, and a second semiconductor layer on the active layer; and
a passivation pattern at least partially surrounding an outer side surface of the nitride semiconductor structure,
wherein the nitride semiconductor structure comprises a convex hemispherical shape.

2. The light-emitting device of claim 1, wherein the light-emitting device further comprises:
a conductive layer in contact with the second semiconductor layer.

3. The light-emitting device of claim 2, wherein a lower surface of the conductive layer is coplanar with a lower surface of the passivation pattern.

4. The light-emitting device of claim 1, wherein the passivation pattern covers an outer side surface of the active layer and an outer side surface of the second semiconductor layer, and covers a portion of a convex outer surface of the first semiconductor layer without covering a remaining portion of the convex outer surface of the first semiconductor layer.

5. The light-emitting device of claim 4, wherein the passivation pattern comprises a ring shape covering the portion of the convex outer surface of the first semiconductor layer except for the remaining portion of the convex outer surface in a plan view of the light-emitting device.

6. The light-emitting device of claim 1, wherein the first semiconductor layer includes a protrusion that covers an upper surface of the passivation pattern,
wherein a width of a portion of the first semiconductor layer on which the passivation pattern is disposed is less than a width of a portion of the first semiconductor layer on which the passivation pattern is not disposed.

7. The light-emitting device of claim 1, wherein the nitride semiconductor structure further comprises:
a conductive layer in contact with the second semiconductor layer,
wherein the nitride semiconductor structure has a semi-cylindrical shape having a length in a first direction and a height in a second direction.

8. The light-emitting device of claim 7, wherein a ratio of the height and the length of the semi-cylindrical shape is in a range of 1:1 to 1:10.

9. The light-emitting device of claim 7, wherein the nitride semiconductor structure comprises a stack structure in which the first semiconductor layer, the active layer, and the second semiconductor layer are sequentially stacked along the second direction of the semi-cylindrical shape.

10. The light-emitting device of claim 7, wherein the nitride semiconductor structure has a structure in which the first semiconductor layer, the active layer, and the second semiconductor layer are sequentially arranged along the first direction of the semi-cylindrical shape.

11. The light-emitting device of claim 7, wherein the passivation pattern covers a convex side surface of the semi-cylindrical shape without covering a flat outer surface of the semi-cylindrical shape that is opposite to the convex side surface of the semi-cylindrical shape.

12. A display device comprising:
a package substrate;
a first electrode on the package substrate;
a light-emitting element on the first electrode, the light-emitting element including:
a nitride semiconductor structure having a convex hemispherical shape, the nitride semiconductor structure including a first semiconductor layer, an active layer on the first semiconductor layer, and a second semiconductor layer on the active layer; and
a passivation pattern at least partially surrounding an outer side surface of the nitride semiconductor structure, and
a second electrode on the first semiconductor layer of the light-emitting element.

13. The display device of claim 12, wherein the light-emitting element further comprises:
a conductive layer having a first surface and a second surface that is opposite the first surface, the first surface in contact with the second semiconductor layer, and the second surface in contact with the first electrode.

14. The display device of claim 12, wherein the nitride semiconductor structure further comprises:
a conductive layer in contact with the second semiconductor layer,
wherein the nitride semiconductor structure has a semi-cylindrical shape having a length in a first direction and a height in a second direction.

15. The display device of claim 14, wherein a ratio of the height and the length of the semi-cylindrical shape is in a range of 1:1 to 1:10.

16. The display device of claim 14, wherein the nitride semiconductor structure comprises a stack structure in which the first semiconductor layer, the active layer, and the second semiconductor layer are sequentially stacked along the second direction of the semi-cylindrical shape.

17. The display device of claim 14, wherein the nitride semiconductor structure has a structure in which the first semiconductor layer, the active layer, and the second semiconductor layer are sequentially arranged along the first direction of the semi-cylindrical shape.

18. The display device of claim 12, wherein the passivation pattern covers an outer side surface of the active layer and an outer side surface of the second semiconductor layer, and covers a portion of a convex outer surface of the first semiconductor layer without covering a remaining portion of the convex outer surface of the first semiconductor layer.

19. A method for manufacturing a light-emitting device, the method comprising:
providing a growth substrate;
forming a trench in the growth substrate, the trench having a concave shape;
forming a passivation pattern on an inner surface of the trench without completely covering the inner surface of the trench;
forming a nitride semiconductor structure by filling the trench with the nitride semiconductor structure;
forming a conductive layer on the nitride semiconductor structure in the trench; and
removing the growth substrate from the nitride semiconductor structure.

20. The method of claim 19, wherein forming the nitride semiconductor structure comprises forming a first semiconductor layer in the trench, forming an active layer on the first semiconductor layer in the trench, and forming a second semiconductor layer on the active layer in the trench,
wherein one surface of the nitride semiconductor structure has a hemispherical shape in which a portion within the trench is convex.

21. The method of claim 20, wherein the second semiconductor layer is formed to contact the conductive layer.

22. The method of claim 20, wherein the nitride semiconductor structure is formed to have a semi-cylindrical shape with a length in a first direction and a height in a second direction.

23. The method of claim 22, wherein the first semiconductor layer, the active layer, and the second semiconductor layer of the nitride semiconductor structure are sequentially stacked in the second direction of the semi-cylindrical shape,
wherein the conductive layer contacts one surface of the second semiconductor layer.

24. The method of claim 22, wherein the first semiconductor layer, the active layer, and the second semiconductor layer of the nitride semiconductor structure are sequentially formed in the first direction of the semi-cylindrical shape.

25. A light-emitting device comprising:
a nitride semiconductor structure having a planar lower surface and a convex upper surface that extends from the planar lower surface in a direction away from the planar lower surface, the nitride semiconductor structure including an active layer configured to emit light; and
a passivation pattern that surrounds at least a portion of the convex upper surface of the nitride semiconductor structure.

26. The light-emitting device of claim 25, wherein the nitride semiconductor structure comprises:
a first semiconductor layer;
a second semiconductor layer, the active layer between the first semiconductor layer and the second semiconductor layer; and
a conductive layer in contact with the second semiconductor layer.

27. The light-emitting device of claim 25, wherein the passivation pattern surrounds a portion of the convex upper surface of the nitride semiconductor structure without surrounding a remaining portion of the convex upper surface of the nitride semiconductor structure and without surrounding the planar lower surface.

28. The light-emitting device of claim 25, wherein the passivation pattern surrounds the convex upper surface of the nitride semiconductor structure in its entirety without surrounding the planar lower surface.
